(19) United States
(12) Patent Application Publication
(10) Pub. No.: US 2007/0296457 A1
(43) Pub. Date: Dec. 27, 2007

(54) Programmable Logic Circuit Control Apparatus, Programmable Logic Circuit Control Method and Program

(75) Inventor: Syuichi Kikuchi, Miyagi (JP)

Correspondence Address: BAKER & MCKENZIE LLP;PATENT DEPARTMENT, 2001 ROSS AVENUE, SUITE 2300, DALLAS, TX, 75201, US

(73) Assignee: TOKYO ELECTRON LIMITED, Tokyo (JP)

(21) Appl. No.: 10/598,151

(22) PCT Filed: Feb. 21, 2005
(86) PCT No.: PCT/JP05/03226

§ 371 Date: Jun. 7, 2007

(30) Foreign Application Priority Data
Feb. 19, 2004 (JP) 2004-042701

(51) Int. Cl. H03K 19/173

(52) U.S. Cl. 326/38

(57) ABSTRACT

Disclosed is a programmable logic circuit control apparatus capable of managing data with various bit widths and data lengths, generated by various processes to be executed by a programmable logic circuit, with a simple structure. A module address memory section (4) stores data indicating addresses of modules or conditions for branching processes and jump distances page by page. A write address and a read address of an internal data memory (2) are also stored in a page where the address of a module is stored. A circuit control section (5) reads data of each page from the module address memory section (4), and, according to the read data, reads a module, reconfigures a programmable logic circuit and reads data of a next page, or performs jump. When the programmable logic circuit is to be reconfigured, the circuit control section (5) performs an operation of supplying a write address and a read address to the internal data memory (2).

### TECHNICAL FIELD

The present invention relates to a programmable logic circuit control apparatus, a programmable logic circuit control method and a program.

### BACKGROUND ART

Programmable logic circuits, such as a field programmable gate array (FPGA) (e.g., XC series by XILINX Ltd. in U.S.A.) and a programmable logic device (PLD), are used widely in developing application specific integrated circuits (ASICs). Programmable logic circuits have a characteristic such that the logical structure of an internal logic circuit can be changed freely based on circuit information loaded. Those programmable logic circuits contribute to shortening the period of altering the specifications of ASICs and the development periods of ASIC products.

Logical structures that are demanded of recent ASICs are becoming more complex and are increasing in integration scale. There are cases where an ASIC is constructed by using several to several tens of programmable logic circuits.

In even a large-scale logic circuit, however, not all programmable logic circuits are always operating. In this respect, there have been proposals to achieve different functions at different timings by reconfiguring a programmable logic circuit (e.g., see Unexamined Japanese Patent Application KOKAI Publication No. 2001-202236). Such reconfiguration of a programmable logic circuit can make the integration scale of an ASIC.

Reconstruction of a programmable logic circuit however requires loading of circuit information of the entire programmable logic circuit. Further, reconfiguration during processing however requires that the processing should be interrupted, data which has been used at the time of interruption should be saved, and circuit information of a new programmable logic circuit and new data which is to be processed by the new programmable logic circuit should be loaded. Those reconfigurations take time. To shorten the times for saving and loading data, there are several schemes proposed, such as the one disclosed in Unexamined Japanese Patent Application KOKAI Publication No. 2001-202236 which provides a programmable logic circuit with a cache memory to shorten the times.

In general, however, the bit widths and lengths of data, generated by processes to be executed by a programmable logic circuit, differ process by process. In reconfiguring a programmable logic circuit, therefore, a memory area for storing generated data should be provided for each process that is executed by the programmable logic circuit. This significantly increases the required amount of a cache memory, thus complicating the structure of a programmable logic circuit.

### DISCLOSURE OF INVENTION

Accordingly, it is an object of the present invention to provide a programmable logic circuit control apparatus, a programmable logic circuit control method and a program, which can manage data with various bit widths and data lengths, generated by various processes to be executed by a programmable logic circuit, with a simple structure.

To achieve the object, according to the first aspect of the invention, there is provided a programmable logic circuit control system, which acquires a module comprised of data defining a logical structure of a programmable logic circuit to be controlled having a function of changing the logical structure according to a supplied control signal, and changes the logical structure of the programmable logic circuit to be controlled based on the acquired module, and which comprises:

a controller which controls the logical structure of the programmable logic circuit to be controlled by supplying a control signal to the programmable logic circuit to be controlled;

a module memory which stores a plurality of modules each comprised of data defining the logical structure of the programmable logic circuit to be controlled;

a module designation memory which has a plurality of ordered memory positions and stores data designating an address of a module at least one of the memory positions;

a node value memory which receives a signal generated at a predetermined node of the programmable logic circuit to be controlled and stores a value represented by the signal,

wherein the node value memory has a plurality of memory positions to which read addresses different from one another and write addresses different from one another are respectively allocated, and has a write function of writing a value represented by the signal generated at the predetermined node of the programmable logic circuit to be controlled at that memory position to which a write address indicated by a write address signal supplied is allocated, a read function of supplying the programmable logic circuit to be controlled with a signal representing a value stored at that memory position to which a read address indicated by a read address signal supplied is allocated,

a read address and a write address associated with a module are further stored at that memory position in the module designation memory where data designating an address of that module is stored, and

the controller has a function of acquiring data stored at a memory position in the module designation memory, a function of acquiring a module indicated by an address included in the data acquired from the module designation memory, generating a control signal for causing the programmable logic circuit to be controlled to take a logical structure indicated by the module, and supplying the control signal to the programmable logic circuit to be controlled, thereby changing the logical structure of the programmable logic circuit to be controlled, and a function of supplying a read address and a write address included in the data acquired from the module designation memory to the node value memory.

This programmable logic circuit control system can manage data generated by processes to be executed by the programmable logic circuit and new data input according to reconfiguration of the programmable logic circuit, with a simple structure, and does not require memory areas prepared process by process. The same is true for new data which have different bit widths and different data lengths.

The controller may be formed by changing a part of the logical structure of the programmable logic circuit. In this case, that part of the logical structure which is changed by the controller can include a portion which constitutes the controller itself.

The node value memory may be formed by changing a part of the logical structure of the programmable logic circuit. In this case, that part of the logical structure which is changed by the controller can include a portion which constitutes the node value memory.

When the controller and/or the node value memory is formed by changing a part of the logical structure of a programmable logic circuit to be controlled, the physical structure of the programmable logic circuit is further simplified.

The node value memory may be constructed in such a way as to be able to independently perform the write function and the read function.

In this case, if the controller has a structure capable of supplying a write address and a read address to the node value memory, writing and reading of a signal value to and from the node value memory are executed efficiently.

The module designation memory may store an address of a module or data designating another memory area at each memory position.

In this case, the controller may behave as follows.

The controller discriminates whether data acquired from a memory position in the module designation memory designates an address of a module or data designating another memory area. The controller acquires the module indicated by the address from the module memory when discriminating that the data designates the address of the module. Then, the controller generates a control signal for causing the programmable logic circuit to be controlled to take a logical structure indicated by the module, and supplies the control signal to the programmable logic circuit. The controller changes the logical structure of the programmable logic circuit this way.

The controller acquires data stored at another memory position from the module designation memory when discriminating that the acquired from the module designation memory designates the another memory position.

With such a structure, even when the process of changing the logical structure of a programmable logic circuit is a complex procedure including a branch process, the process is executed easily and smoothly.

The data stored at a memory position in the module designation memory and designating the another memory position may include condition definition data designating a condition to go to a process of acquiring data stored at the another memory position.

In this case, when discriminating that the data designates the another memory position, the controller discriminates whether the condition designated by the condition definition data included in the acquired data is fulfilled or not. When discriminating that the condition is fulfilled, the controller acquires data stored at the another memory position from the module designation memory, and when discriminating that the condition is not fulfilled, the controller aborts acquisition of data from the another memory position.

With such a structure, even when the process of changing the logical structure of a programmable logic circuit is a procedure including a conditional jump, the process is executed easily and smoothly.

The condition designated by the condition definition data included may relate to a value represented by a signal generated at a predetermined node of the programmable logic circuit to be controlled.

In this case, the controller may behave as follows.

When discriminating that the data acquired from the module designation memory designating another memory position, the controller acquires the signal form the node of the programmable logic circuit to be controlled. Then, based on the value represented by the acquired signal, the controller discriminates, whether the condition designated by the condition definition data included in the data acquired from the module designation memory is fulfilled or not.

The data stored at a memory position in the module designation memory may include identification data for identifying which one of an address of a module and another memory position the data designates.

In this case, the controller may behave as follows.

The controller extracts the identification data from the data acquired from the module designation memory. Then, the controller discriminates whether the acquired data designates an address of a module or data designating another memory area.

In an initial state, the controller may read a module designated by a module address stored at a top one of the ordered memory areas, and control a structure of a programmable logic circuit in such a way as to start an operation.

In this case, when a predetermined condition to change a module is fulfilled, the controller reads a write address corresponding to that module which is currently being executed, and write a value obtained by a current logical structure in a memory area designated by the write address.

Then, the controller fetches an address of a module to be executed next, refers to the module designation memory to acquire a read address, reads a value, if any, stored at a position of the read address in the node value memory, sets the value in the programmable logic circuit, and then starts an operation.

A programmable logic circuit control apparatus according to the second aspect of the invention acquires a module comprised of data defining a logical structure of a programmable logic circuit to be controlled having a function of changing said logical structure according to a supplied control signal, from a module memory storing a plurality of modules, and generates a control signal for causing said programmable logic circuit to be controlled to take a logical structure indicated by said acquired module and supplies said control signal to said programmable logic circuit to be controlled, thereby changing said logical structure of said programmable logic circuit to be controlled, and comprises:

a section that acquires data stored at a memory position in a module designation memory, which has a plurality of ordered memory positions and stores data designating an address of a module at least one of the memory positions, from the module designation memory, wherein a read address and a write address allocated to a memory position in a node value memory are further stored at that memory position in the memory positions in the module designation memory where data designating the address of the module is stored,

the node value memory which has a function of storing a value represented by a signal generated at a predetermined node of the programmable logic circuit to be controlled, at a memory position to which a write address locally supplied is allocated, and a function of supplying a signal representing a value stored at a memory position to which a read address locally supplied is allocated, to the programmable logic circuit to be controlled;

a section which supplies a write address included in the acquired data to the node value memory;

a section which acquires a module indicated by an address included in the acquired data from a module memory, and changes a logical structure of the programmable logic circuit to be controlled in such a way as to cause the programmable logic circuit to take a logical structure indicated by the module; and

a section which supplies a read address included in the acquired data to the node value memory.

This programmable logic circuit control apparatus can also manage data generated by processes to be executed by the programmable logic circuit and new data input according to the reconfiguration of the programmable logic circuit, with a simple structure, and does not require memory areas prepared process by process. The same is true for new data which have different bit widths and different data lengths.

When the programmable logic circuit control apparatus itself and/or the node value memory is formed by changing a part of the logical structure of a programmable logic circuit to be controlled, the physical structure of the entire system including the programmable logic circuit is further simplified.

A programmable logic circuit control method according to the third aspect of the invention acquires a module comprised of data defining a logical structure of a programmable logic circuit to be controlled, and changes the logical structure of the programmable logic circuit to be controlled based on the acquired module, and comprises the steps of:

storing a plurality of modules each comprised of data defining the logical structure of the programmable logic circuit to be controlled;

acquiring data designating an address of a module and a signal generated at a predetermined node of the programmable logic circuit to be controlled, and stores a read address and a write address, allocated to that memory area in the node value memory which stores a value represented by the signal, at least one of a plurality of ordered memory positions for module use order designation;

acquiring data stored at the memory positions for module use order designation;

supplying a write address included in the acquired data to the node value memory;

acquiring a module indicated by an address included in the acquired data from the module memory, generating a control signal to cause the programmable logic circuit to be controlled to take a logical structure indicated by the module, and supplying the control signal to the programmable logic circuit to be controlled to change the logical structure of the programmable logic circuit to be controlled; and

supplying a read address included in the acquired data to the node value memory,

wherein the node value memory has a function of storing a value represented by a signal generated at a predetermined node of the programmable logic circuit to be controlled, at a memory position to which a write address locally supplied is allocated, and a function of supplying a signal representing a value stored at a memory position to which a read address locally supplied is allocated, to the programmable logic circuit to be controlled.

This programmable logic circuit control method does not require that memory areas for storing data generated by processes to be executed by the programmable logic circuit and data input according to the reconfiguration of the programmable logic circuit should be prepared process by process, and can manage the data with a simple structure. The same is true for new data which have different bit widths and different data lengths.

When the node value memory is formed by changing a part of the logical structure of a programmable logic circuit to be controlled, the physical structure of the entire system that executes the programmable logic circuit control method is further simplified.

A programmable logic circuit control method according to the fourth aspect of the invention acquires a module comprised of data defining a logical structure of a programmable logic circuit to be controlled having a function of changing the logical structure according to a supplied control signal, from a module memory storing a plurality of modules, and generates a control signal for causing the programmable logic circuit to be controlled to take a logical structure indicated by the acquired module and supplies the control signal to the programmable logic circuit to be controlled, thereby changing the logical structure of the programmable logic circuit to be controlled, and comprises the steps of:

acquiring data stored at a memory position in a module designation memory, which has a plurality of ordered memory positions and stores data designating an address of a module at least one of the memory positions, from the module designation memory, wherein a read address and a write address allocated to a memory position in a node value memory are further stored at that memory position in the memory positions in the module designation memory where data designating the address of the module is stored, and the node value memory has a function of storing a value represented by a signal generated at a predetermined node of the programmable logic circuit to be controlled, at a memory position to which a write address locally supplied is allocated, and a function of supplying a signal representing a value stored at a memory position to which a read address locally supplied is allocated, to the programmable logic circuit to be controlled;

supplying a write address included in the acquired data to the node value memory;

acquiring a module indicated by an address included in the acquired data from a module memory, and changing a logical structure of the programmable logic circuit to be controlled in such a way as to cause the programmable logic circuit to take a logical structure indicated by the module; and

supplying a read address included in the acquired data to the node value memory.

This programmable logic circuit control method can also manage data generated by processes to be executed by the programmable logic circuit and new data input according to the reconfiguration of the programmable logic circuit, with a simple structure, and does not require memory areas prepared process by process. The same is true for new data which have different bit widths and different data lengths.

When the node value memory is formed by changing a part of the logical structure of a programmable logic circuit to be controlled, the physical structure of the entire system that executes the programmable logic circuit control method is further simplified.

A program according to the fifth aspect of the invention allows a computer to function as a controller which supplies a control signal to a programmable logic circuit to be controlled having a function of changing a logical structure according to the supplied control signal, thereby changing the logical structure of the programmable logic circuit to be controlled;

a module memory which stores a plurality of modules each comprised of data defining the logical structure of the programmable logic circuit to be controlled;

a module designation memory which has a plurality of ordered memory positions and stores data designating an address of a module at least one of the memory positions; and

a node value memory which acquires a signal generated at a predetermined node of the programmable logic circuit to be controlled and stores a value represented by the signal,

wherein the node value memory has a plurality of memory positions to which read addresses and write addresses are allocated, and has a write function of storing a value represented by the signal generated at the predetermined node of the programmable logic circuit to be controlled at that memory position to which a write address locally supplied is allocated, a read function of supplying the programmable logic circuit to be controlled with a signal representing a value stored at that memory position to which a read address locally supplied is allocated,

a read address and a write address are further stored at that memory position in the module designation memory where data designating an address of that module is stored, and

the controller acquires data stored at a memory position in the module designation memory, supplies a write address included in the acquired data to the node value memory, acquires a module indicated by an address included in the data acquired from the module designation memory, generates a control signal for causing the programmable logic circuit to be controlled to take a logical structure indicated by the module, and supplies the control signal to the programmable logic circuit to be controlled, thereby changing the logical structure of the programmable logic circuit to be controlled, and supplies a read address included in the acquired data to node value memory.

The computer that runs such a program does not require that memory areas for storing data generated by processes to be executed by the programmable logic circuit and data input according to the reconfiguration of the programmable logic circuit should be prepared process by process, and can manage the data with a simple structure. The same is true for new data which have different bit widths and different data lengths.

A program according to the sixth aspect of the invention allows a computer to function as a programmable logic circuit control apparatus which acquires a module comprised of data defining a logical structure of a programmable logic circuit to be controlled having a function of changing the logical structure according to a supplied control signal, from a module memory storing a plurality of modules, and generates a control signal for causing the programmable logic circuit to be controlled to take a logical structure indicated by the acquired module and supplies the control signal to the programmable logic circuit to be controlled, thereby changing the logical structure of the programmable logic circuit to be controlled,

the programmable logic circuit control apparatus comprising:

a section that acquires data stored at a memory position in a module designation memory, which has a plurality of ordered memory positions and stores data designating an address of a module at least one of the memory positions, from the module designation memory, wherein a read address and a write address allocated to a memory position in a node value memory are further stored at that memory position in the memory positions in the module designation memory where data designating the address of the module is stored,

the node value memory which has a function of storing a value represented by a signal generated at a predetermined node of the programmable logic circuit to be controlled, at a memory position to which a write address locally supplied is allocated, and a function of supplying a signal representing a value stored at a memory position to which a read address locally supplied is allocated, to the programmable logic circuit to be controlled;

a section which supplies a write address included in the acquired data to the node value memory;

a section which acquires a module indicated by an address included in the acquired data from a module memory, and changes a logical structure of the programmable logic circuit to be controlled in such a way as to cause the programmable logic circuit to take a logical structure indicated by the module; and

a section which supplies a read address included in the acquired data to the node value memory.

The computer that runs such a program can manage data generated by processes to be executed by the programmable logic circuit and new data input according to the reconfiguration of the programmable logic circuit, with a simple structure, and does not require memory areas prepared process by process. The same is true for new data which have different bit widths and different data lengths.

When the node value memory is formed by changing a part of the logical structure of a programmable logic circuit to be controlled, the physical structure of the entire system including a computer that executes the program is simplified.

As apparent from the above, the invention can realize a programmable logic circuit control apparatus, a programmable logic circuit control method and a program, which can manage data generated by processes to be executed by a programmable logic circuit, with a simple structure.

### BRIEF DESCRIPTION OF DRAWINGS

These objects and other objects and advantages of the present invention will become more apparent upon reading of the following detailed description and the accompanying drawings in which:

FIG. 1 is a diagram showing the structure of a programmable logic circuit control apparatus according to one embodiment of the present invention;

FIG. 2 is a diagram exemplarily showing the structure of a programmable logic circuit;

FIG. 3 is a diagram showing the structure of a logic circuit BIBC;

FIG. 4 is a diagram showing the structure of a logic circuit BFBC;

FIG. 5 is a diagram showing the structure of a logic circuit BOBC;

FIG. 6A is a diagram showing the structure of a matrix switch, and FIG. 6B is a diagram showing the structure of switches constituting the matrix switch;

FIG. 7 is a diagram exemplarily showing the data structure of data to be stored in a module address memory section; and

FIG. 8 is a flowchart illustrating the flow of processes that are executed by a circuit control section.

### BEST MODE FOR CARRYING OUT THE INVENTION

A preferred embodiment of the invention as a programmable logic circuit control apparatus will be described below with reference to the accompanying drawings.

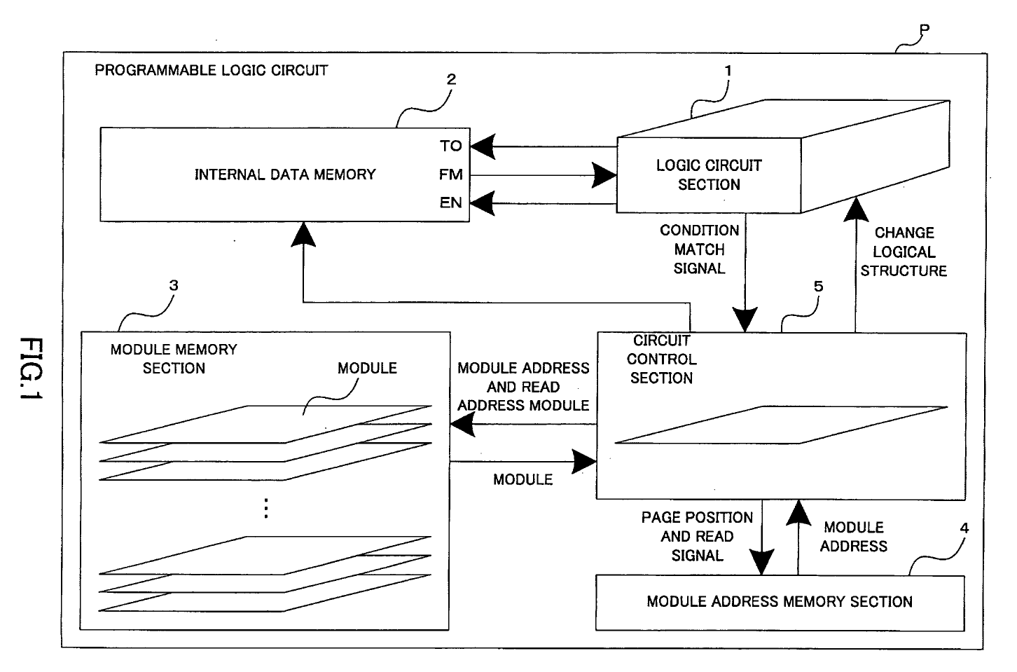

FIG. 1 is a diagram showing the structure of the programmable logic circuit control apparatus. As illustrated, the programmable logic circuit control apparatus comprises a programmable logic circuit P.

The programmable logic circuit P comprises a configurable logic block (CLB), which is used to construct a field programmable gate array (FPGA) by XILINX Ltd. in U.S.A., a matrix switch, wiring materials and the like. The programmable logic circuit P changes (reconfigures) its logical structure (the correlation between its input signal and its output signal) according to a control signal supplied externally or generated by the programmable logic circuit P.

The programmable logic circuit P includes a logic circuit section 1, an internal data memory 2, a module memory section 3, a module address memory section 4, and a circuit control section 5. The logic circuit section 1, the internal data memory 2, the module memory section 3 and the module address memory section 4 are formed in such a way as to be connected to the circuit control section 5. The logic circuit section 1 and the internal data memory 2 are formed in such a way as to be connected to each other.

The programmable logic circuit P receives, from, for example, an external computer or another kind of an external unit, control signals designating the logical structures of the internal data memory 2, the module memory section 3, the module address memory section 4 and the circuit control section 5. According to the control signals, the logical structures of the internal data memory 2, the module memory section 3, the module address memory section 4 and the circuit control section 5 are changed. That portion of the programmable logic circuit P which does not constitute the internal data memory 2, the module memory section 3, the module address memory section 4 and the circuit control section 5 is the logic circuit section 1.

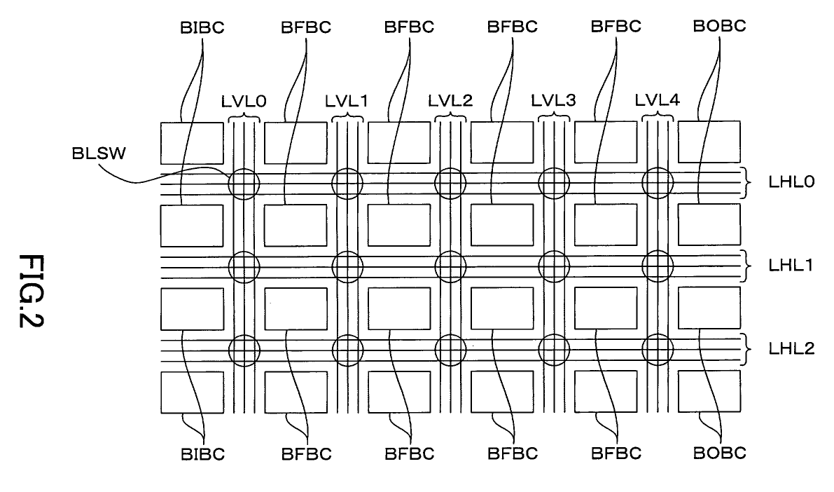

The logic circuit section 1, as exemplified in FIG. 2, comprises input logic circuits BIBC, logic circuits BFBC, output logic circuits BOBC, matrix switches BLSW, wirings LVL0 to LVL4 and wirings LHL0 to LHL2.

Each of the wirings LVL0 to LVL4 and LHL0 to LHL2 is comprised of 63 signal lines. The input logic circuit BIBC, the logic circuit BFBC and the output logic circuit BOBC are respectively connected to the wirings LVL0 to LVL4 via buses. The wirings LVL0 to LVL4 and the wirings LHL0 to LHL2 are switched by the matrix switches BLSW, thereby realizing variable wirings.

The input logic circuit BIBC, the logic circuit BFBC and the output logic circuit BOBC each comprise a logic circuit, such as a TTL (Transistor-Transistor Logic) circuit or a CMOS (Complementary Metal-Oxide-Silicon) logic circuit.

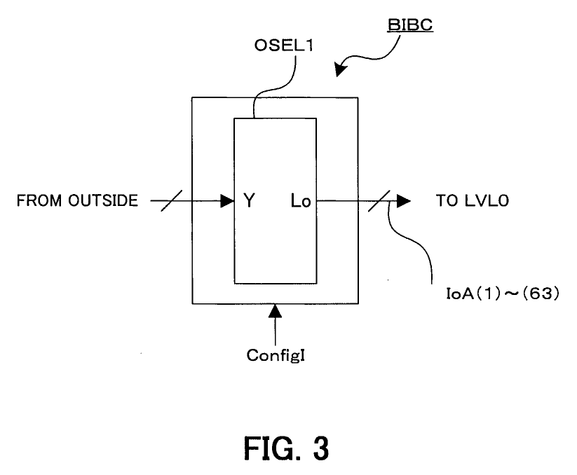

The input logic circuit BIBC supplies an input signal input to the logic circuit section 1 to the wiring LVL0 under the control of the circuit control section 5. Each input logic circuit BIBC comprises, for example, an output selector OSEL1 as shown in FIG. 3.

The output selector OSEL1 is connected to the wiring LVL0 via buses IoA(1) to IoA(63) of 63 bits, and supplies a 4-bit signal input to the logic circuit section 1 to the signal lines that constitute the wiring LVL0. It is to be noted that based on the value of a 24-bit control signal ConfigI supplied from the circuit control section 5 or so, the output selector OSEL1 decides to which signal lines in the wiring LVL0 the signal is to be supplied, and supplies the signal to the decided signal lines. The output selector OSEL1 may decide not to supply the signal to any signal line in the wiring LVL0.

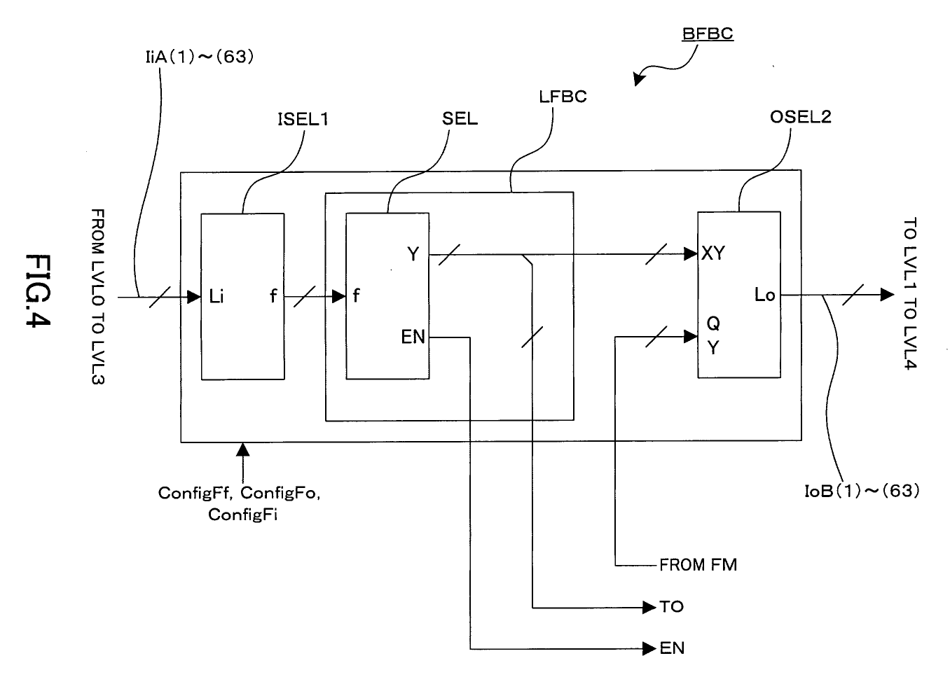

The logic circuit BFBC performs a logical operation on signals supplied from the wirings LVL0 to LVL3 under the control of the circuit control section 5, and supplies acquired signals to the wirings LVL1 to LVL4. As shown in FIG. 4, for example, each logic circuit BFBC includes an input selector ISEL1, a basic functional cell LFBC, and an output selector OSEL2, as shown in FIG. 4.

The input selector ISEL1 is connected to the wirings LVL0 to LVL3 via buses IiA(1) to IiA(63) of 63 bits, acquires a 6-bit signal from a signal supplied from selected one of the wirings LVL0 to LVL3, and supplies the acquired signal to the basic functional cell LFBC. It is to be noted that based on the value of a 36-bit control signal ConfigFi supplied from the circuit control section 5 or so, the input selector ISEL1 decides from which six signal lines in the 63 signal lines constituting the wiring LVL0 to LVL3 the signal is to be acquired, and supplies the acquired signal to the basic functional cell LFBC. The input selector ISEL1 may decide not to acquire a signal from any signal line in the wiring LVL0 to LVL3. In this case, a signal representing a log value “0” is supplied to the basic functional cell LFBC.

As shown in FIG. 4, for example, the basic functional cell LFBC includes a selector SEL. Based on the value of the 6-bit signal supplied from the input selector ISEL1, the selector SEL selects a total of two bits, one bit from the first to sixty-fourth bits of a 130-bit control signal ConfigFf supplied from the circuit control section 5 or so, and one bit from 65-th to 128-th bits. The 2-bit signal (signal XY) is supplied to the output selector OSEL2 and to an input port TO (to be discussed later) of the internal data memory 2. The basic functional cell LFBC decides whether or not to store the signal XY in the internal data memory 2 based on the value of the 129-th and 130-th bits in the control signal ConfigFf. The basic functional cell LFBC supplies control data indicative of the result of the decision to an enable terminal EN (to be discussed later) of the internal data memory 2. The control data may take, for example, a value “1” when indicating storage of the signal XY and a value “0” when indicating that the signal XY is not to be stored.

The output selector OSEL2 is connected to the wirings LVL1 to LVL4 via buses IoB(1) to IoB(63) of 63 bits, and supplies a total of four bits, the signal XY supplied from the basic functional cell LFBC and two bits read from the internal data memory 2 and output from an output port FM (to be discussed later), to the signal lines that constitute the wirings LVL1 to LVL4. It is to be noted that based on the value of a 24-bit control signal ConfigFo supplied from the circuit control section 5 or so, the output selector OSEL2 decides to which signal lines in the wirings LVL1 to LVL4 the 4-bit signal is to be supplied, and supplies the signal to the decided signal lines. The output selector OSEL2 may decide not to supply the signal to any signal line of the wirings LVL1 to LVL4.

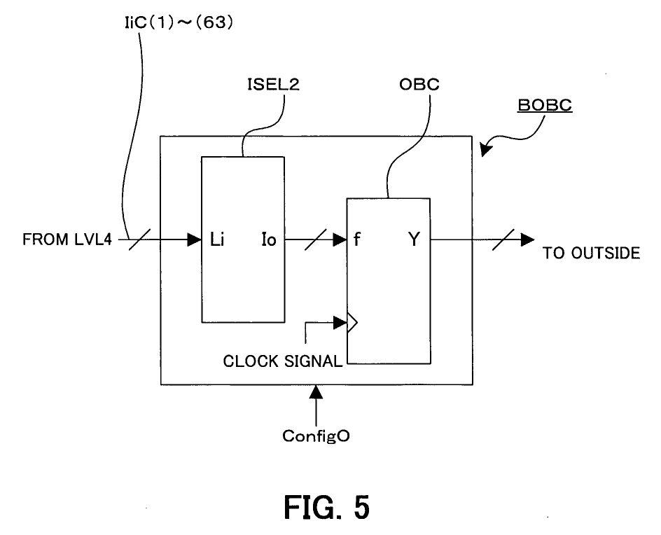

The output logic circuit BOBC comprises a logic circuit which outputs a signal, supplied from the wiring LVL4, under the control of the circuit control section 5. Each logic circuit BOBC includes, for example, an input selector ISEL2 and a functional cell OBC, as shown in FIG. 5.

The input selector ISEL2 is connected to the wiring LVL4 via buses IiC(1) to IiC(63) of 63 bits, acquires a 4-bit signal from a signal supplied from the connected wiring LVL4, and supplies the acquired signal to the functional cell OBC. It is to be noted that based on the values of the first to twenty-fourth bits in a 28-bit control signal ConfigO supplied from the circuit control section 5 or so, the input selector ISEL2 decides from which four signal lines in the 63 signal lines constituting the wiring LVL4 the 4-bit signal is to be acquired, and supplies the acquired signal to the functional cell OBC. The input selector ISEL2 may decide not to acquire a signal from any signal line in the wiring LVL4, in which case, a signal representing a log value “0” is supplied to the functional cell OBC.

The functional cell OBC comprises a latch circuit, holds the value of the 4-bit signal supplied from the input selector ISEL2, or passes this signal. The functional cell OBC decides whether to hold or pass the signal based on the values of the 25-th to 28-th bits in the control signal ConfigO. The functional cell OBC sends out a signal having the held value or the passed signal as a signal Y. The logic circuit section 1 acquires a clock signal externally or has a circuit which generates a clock signal, and the individual components of the logic circuit section 1 should latch a signal in synchronism with the clock signal.

The matrix switches BLSW are capable of electrically connecting and disconnecting the wirings LVL0 to LVL4 and the wirings LHL0 to LHL2 from one another. The matrix switches BLSW electrically connect or disconnect the wirings LVL0 to LVL4 from one to another, or electrically connect or disconnect the wirings the wirings LHL0 to LHL2 from one another, or electrically connect or disconnect the wirings LVL0 to LVL4 to or from the wirings LHL0 to LHL2, according to the value of a control signal (which will be hereinafter called control signal ConfigL) supplied from the circuit control section 5 or so.

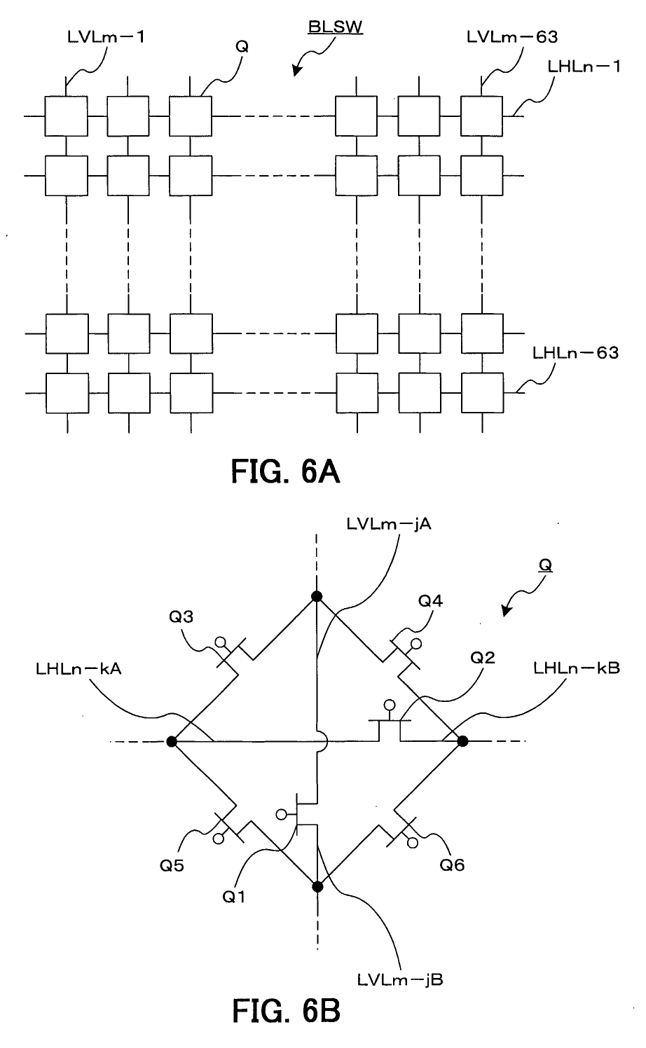

As shown in FIG. 6A, for example, the matrix switch BLSW which switches between the wiring LVLm (m being an integer from 0 to 4) and the wiring LHLn (n being an integer from 0 to 2) comprises a total of 3969 switch groups Q which switch between signal lines LVLm-j (j being an integer from 1 to 63) and signal lines LHLn-k (k being an integer from 1 to 63). Each switch groups Q comprises switching elements, such as field effect transistors (FETs), as shown in FIG. 6B, for example.

In the example shown in FIG. 6B, an FETQ1 switches between two signal lines LVLm-jA and LVLm-jB constituting the signal lines LVLm-j. An FETQ2 switches between two signal lines LHLn-kA and LHLn-kB constituting the signal lines LHLn-k. An FETQ3 switches between a signal line LVLm-jA and a signal line LHLn-kA. An FETQ4 switches between a signal line LVLm-jA and a signal line LHLn-kB. An FETQ5 switches between a signal line LVLm-jB and a signal line LHLn-kA. An FETQ6 switches between a signal line LVLm-jB and a signal line LHLn-kB. When the switch group Q has the structure as shown in FIG. 6B, the control signal ConfigL should be applied to, for example, the gates of the individual FETs constituting the switch group Q.

The wirings LVL0 to LVL4 are connected to the input logic circuit BIBC, the logic circuits BFBC, the output logic circuit BOBC and the matrix switches BLSW. The wirings LHL0 to LHL2 are connected to the matrix switches BLSW. The wirings LHL0 to LHL2 are not directly connected to the input logic circuit BIBC, the logic circuits BFBC and the output logic circuit BOBC (but, they may be connected to those logic circuits via the matrix switches BLSW.)

The internal data memory 2 forms a dual port synchronous RAM (Random Access Memory) or the like, and has memory areas associated one to one with the individual logic circuits BFBC. Each memory area of the internal data memory 2 has the memory capacity with a word length long enough to store signals supplied by the logic circuit BFBC associated with that memory area.

As shown in FIG. 1, for example, the internal data memory 2 has the input port TO, the output port FM and the enable terminal EN independent of one another, and has a read address bus and a write address bus independent of each other. The input port TO and the enable terminal EN are connected to the basic functional cell LFBC of the logic circuit BFBC, the output port FM is connected to the output selector OSEL2 of the logic circuit BFBC, and the read address bus and the write address bus are connected to the circuit control section 5.

A read address and a write address are allocated to each of memory positions which form a memory area of the internal data memory 2. When the internal data memory 2 detects that a signal indicative of storage of data is supplied to the enable terminal EN, the internal data memory 2 stores a signal supplied to the input port TO upon detection in the memory area that is indicated by the write address supplied from the write address bus. The internal data memory 2 reads a signal from the memory area that is indicated by the read address supplied from the read address bus, and outputs the signal from the output port FM. The internal data memory 2 can perform the operation of storing a signal and the operation of reading and outputting a signal in parallel.

In response to an access by the circuit control section 5, the module memory section 3 and the module address memory section 4 read data (to be discussed later) stored themselves, and supply the data to the circuit control section 5. It is to be noted that data to be stored in the module memory section 3 and the module address memory section 4 has been supplied from an external unit before the circuit control section 5 performs an operation to be discussed later, and is stored in memory areas in the module memory section 3 and the module address memory section 4.

The module memory section 3, as exemplified in FIG. 1, stores data (hereinafter referred to as “module”) defining the logical structure of the programmable logic circuit P. A single module indicates the entire or a part of the logical structure that can be expressed at a time by a single programmable logic circuit P. Therefore, the module may indicate the logical structures of all of the input logic circuit BIBC, the logic circuit BFBC, the output logic circuit BOBC and the internal data memory 2. The module may be the one as disclosed in Unexamined Japanese Patent Application KOKAI Publication No. 2003-198362 or Unexamined Japanese Patent Application KOKAI Publication No. 2003-29969, which forms the logical structure of a part of the logic circuit BFBC or a part of the internal data memory 2 without changing the logical structures of the other logic circuits.

A 10-bit address is allocated to each of the memory positions constituting a memory area in the module memory section 3. The module memory section 3 can specify a module by specifying the address of the module, i.e., specifying the address of the top memory position (or a given part in the module, such as the end position) where the module is stored.

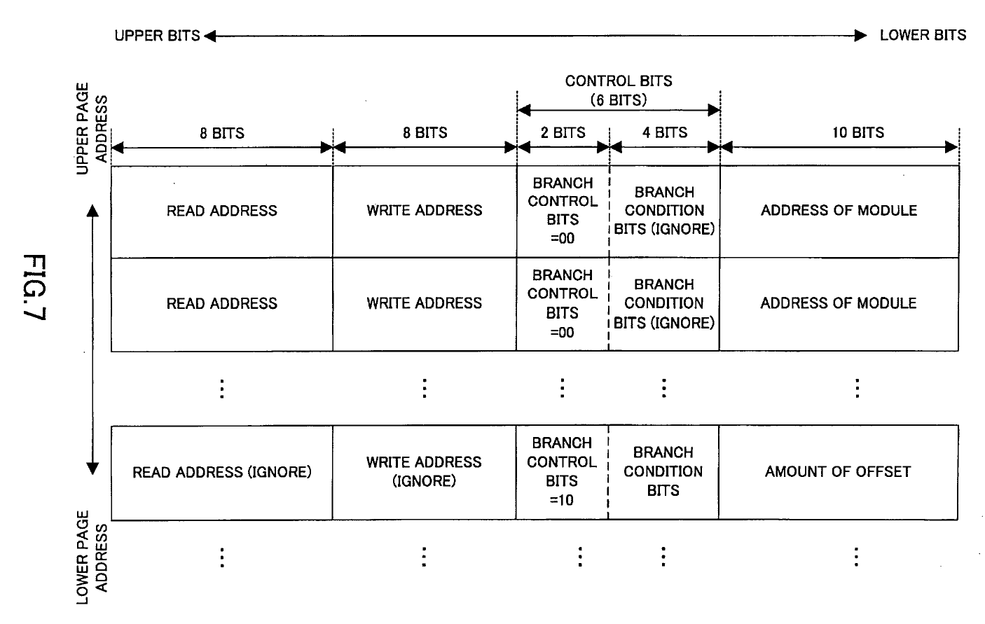

As shown in FIG. 7, each memory area in the module address memory section 4 forms one page every 32 bits. A page address is allocated to each page, and individual pages of the module address memory section 4 are ordered from an upper level to a lower one based on the page addresses. The 32 bits constituting each page are likewise ordered from the most significant bit to the least significant bit.

A data structure in the module address memory section 4 is exemplified in FIG. 7.

Stored in each page of the module address memory section 4 are the address of each module stored in the module memory section 3 or the value indicative of the jump distance (offset value) when a branch process is carried out, a 6-bit control bit, an 8-bit write address, and an 8-bit read address. In the example shown in FIG. 7, the address of a module or the offset value, the control bit, the write address, and the read address respectively occupy each page by 10 bits, 6 bits, 8 bits and 8 bits in order from the least significant bit.

The control bit consists of, for example 2 bits indicative of whether or not to permit the circuit control section 5 to perform branching (hereinafter called “branch control bit”), and 4 bits indicative of a branch condition when branching takes place (hereinafter called “branch condition definition bit”).

When the branch control bit takes a predetermined value (e.g., a binary value of “10”) and when the condition indicated by the branch condition bit included in the same page as the branch control bit is located is fulfilled, the branch control bit instructs the circuit control section 5 to jump by the offset value stored in that page with the page address of the page as the origin (i.e., to read data stored in a page whose page address is the sum of the page address of that same page and the offset value stored in that page).

When the branch control bit takes a value other than the predetermined value (e.g., a binary value of “00” or “01”), the branch control bit instructs the circuit control section 5 to read from the module memory section 3 a module specified by the address included in the same page as the branch control bit is located, reconfigure the logic circuit section 1 indicated by the read module, and read data stored in the next page to that same page (specifically, the page whose page address is the page address of that page incremented by “1”).

When the branch condition bit takes a binary value of “0000”, for example, it indicates a condition for executing a jump is that “signal Cond(0) has a value “0””.

When the branch condition bit takes a binary value of “0001”, for example, it indicates a condition for executing a jump is that “signal Cond(1) has a value “0””.

When the branch condition bit takes a binary value of “0010”, for example, it indicates a condition for executing a jump is that “signal Cond(2) has a value “0””.

When the branch condition bit takes a binary value of “0011”, for example, it indicates a condition for executing a jump is that “signal Cond(3) has a value “0””.

When the branch condition bit takes a binary value of “0100”, for example, it indicates a condition for executing a jump is that “signal Cond(4) has a value “0””.

When the branch condition bit takes a binary value of “1000”, for example, it indicates a condition for executing a jump is that “signal Cond(0) has a value “1””.

When the branch condition bit takes a binary value of “1001”, for example, it indicates a condition for executing a j ump is that “signal Cond(1) has a value “1””.

When the branch condition bit takes a binary value of “1010”, for example, it indicates a condition for executing a jump is that “signal Cond(2) has a value “1””.

When the branch condition bit takes a binary value of “1011”, for example, it indicates a condition for executing a jump is that “signal Cond(3) has a value “1””.

When the branch condition bit takes a binary value of “1100”, for example, it indicates a condition for executing a jump is that “signal Cond(4) has a value “1””.

When the branch condition bit takes a binary value of “0111” or “1111”, for example, it indicates a condition that a jump should always be done as long as the branch control bit included in the same page as the branch condition bit is located has the predetermined value”.

The signals Cond(0) to Cond(4) are signals of a total of 5 bits to be supplied to the circuit control section 5 by the logic circuit BFBC which are monitoring if the conditions are fulfilled, the output logic circuit BOBC which is performing a process of outputting the monitoring result, or a predetermined node in the logic circuit section 1. In which case the logic circuit BFBC, the output logic circuit BOBC or the like supplies the signals Cond(0) to Cond(4) is described, for example, in a module beforehand. Possible targets for monitoring if the condition is fulfilled or not include a condition to invoke another process and a condition to return to the original process from which invoking is done, besides the condition to execute a conditional jump.

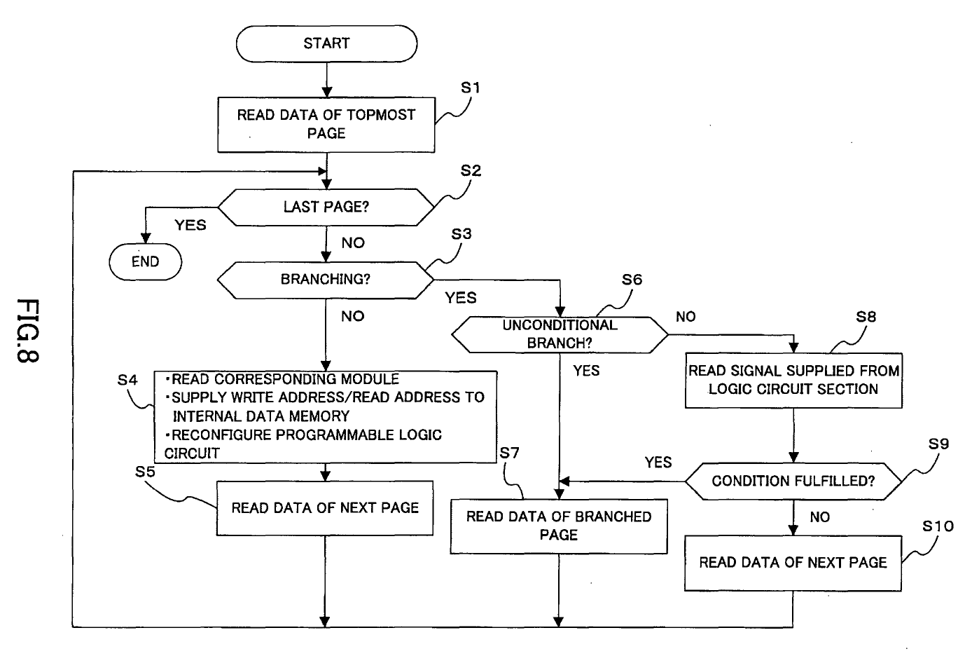

The circuit control section 5 performs, for example, a sequence of processes illustrated in FIG. 8.

When the circuit control section 5 comprises a processor, a non-volatile memory and the like, the processor should load a program stored in, for example, the non-volatile memory and run the program to execute the sequence of processes illustrated in FIG. 8.

When the circuit control section 5 starts operating, the circuit control section 5 first reads data stored in a page having the topmost page address in the module address memory section 4 (i.e., the control bit, and the address of a module or an offset value) (step S1).

Next, the circuit control section 5 discriminates whether the page in which data from the module address memory section 4 has been read at step S7 or step S10 is the last page or not, i.e., the page in question is the page which is given the lowest page address (step S2). When discriminating that it is the last page, the circuit control section 5 terminates the sequence of processes.

When discriminating that it is not the last page, the circuit control section 5 discriminates which one of processes, (a) reading of a module or (b) branching (conditional jump or unconditional jump), the control bit included in the latest data read from the module address memory section 4 indicates (step S3).

When the control bit indicates the process (a), the circuit control section 5 reads the address of a module included in the data read from the module address memory section 4. Next, the circuit control section 5 reads the module designated by the address from the module memory section 3, and reconfigures the individual sections of the programmable logic circuit P in such a way as to take a logical structure expressed by the module (step S4). The individual sections of the programmable logic circuit P include those portions which constitute the internal data memory 2 in addition to those portions which constitute the logic circuit section 1. Specifically, the circuit control section 5 reconfigures the logic circuit section 1 by generating, for example, the control signals ConfigI, ConfigFi, ConfigFf, ConfigFo, ConfigO and ConfigL and supplying the control signals to the logic circuit section 1 at step S4.

At step S4, the circuit control section 5 supplies a write address and a read address included in data read from the module address memory section 4 to the internal data memory 2.

When the logic circuit section 1 is supplied with the control signals at step S4, the logic circuit section 1 performs the process of reading the value of the signal XY from the internal data memory 2 or the process of fetching a signal QY Writing the signal XY or reading the signal QY are carried out with respect to the memory position that is designated by the read address or the write address supplied by the circuit control section 5 to the internal data memory 2, when the writing or the reading has been done.

When the process at step S4 is finished, the circuit control section 5 reads data stored in the next page from the module address memory section 4 (step S5), and returns to step S2.

When the control bit indicates the process (b) at step S3, on the other hand, the circuit control section 5 discriminates whether the branch condition bit included in the control bit indicates (c) unconditional jump or (d) conditional jump (step S6). Specifically, the circuit control section 5 discriminates whether the value of the branch condition bit is “0111” or “1111” and decides that an unconditional jump is instructed when the bit value is either one of the values at step S6. When the bit value is other than those values, the circuit control section 5 decides that a conditional jump is instructed.

When deciding at step S6 that an unconditional jump is instructed, the circuit control section 5 refers to an offset value included in the same page as the control bit is located, jumps by the offset value (i.e., reads data stored in the jumped page) (step S7), and returns to step S2.

When deciding at step S6 that a conditional jump is instructed, the circuit control section 5 acquires, for example, the signals Cond(0) to Cond(4) supplied from the logic circuit section 1 (step S8). Thereafter, based on the acquired signals Cond(0) to Cond(4), the circuit control section 5 discriminates whether the branch condition indicated by the branch condition bit is fulfilled or not (step S9). When deciding that the branch condition is not fulfilled, the circuit control section 5 reads data stored in the next page from the module address memory section 4 (step S10), then returns to step S2. When deciding that the branch condition is fulfilled, however, the circuit control section 5 returns to step S7.

The logic circuit section 1 performs arithmetic operations according to its logical structure when a signal or so externally is supplied to the input logic circuit BIBC, by using the signal. The logic circuit section 1 then outputs a signal indicative of the results of the arithmetic operations from the output logic circuit BOBC.

Executing the steps S1 to S10, the programmable logic circuit control apparatus can reconfigure the programmable logic circuit P in a predetermined order step by step. The programmable logic circuit control apparatus can also smoothly perform reconfiguration involving complicated procedures including conditional branching, returning from a branched point and a loop.

Data that is generated during the processing done by the logic circuit section 1 is held in the internal data memory 2. Even the bit width and data length of the data vary process by process, therefore, it is unnecessary to prepare a memory for each process the logic circuit section 1 executes. Accordingly, the programmable logic circuit control apparatus can be realized easily.

The structure of the programmable logic circuit control apparatus is not limited to the above-described one.

For example, the module memory section 3 may comprise an external RAM or another external memory device.

The internal data memory 2 and the module address memory section 4 may partially or entirely comprise an external RAM or a memory device separate from the one in the programmable logic circuit P. A single memory device may serve as a part or all of the functions of the internal data memory 2, the module memory section 3 and the module address memory section 4.

The circuit control section 5 may comprise a separate processor from the programmable logic circuit P and comprised of, for example, a CPU (Central Processing Unit), and an external memory, such as a ROM (Read Only Memory), where a program the processor runs is stored. Alternatively, the circuit control section 5 may comprise an exclusive electronic circuit separate from the programmable logic circuit P.

That portion of the programmable logic circuit P which is to be reconfigured according to a module should not necessarily be limited to that portion which forms the logic circuit section 1 or that portion which forms the internal data memory 2, but may that portion which forms the module memory section 3 or the module address memory section 4. Further, the portion that forms the circuit control section 5 may be reconfigured.

The signal that is stored in the internal data memory 2 by the logic circuit section 1 is not limited to the signal XY, but the value of an arbitrary signal generated at an arbitrary node by the logic circuit section 1 may be stored.

When the logic circuit section 1 need not perform writing of the value of a signal into the internal data memory 2 and reading of a signal value therefrom in parallel, the internal data memory 2 should not necessarily have a structure which can execute data reading and data writing in parallel.

Data stored in the module address memory section 4 need not take the data structure discussed above. For example, the number of bits constituting a page is arbitrary. Further, the quantities of bits of the address of a module, a page address, a write address, a read address, an offset value, and the branch control bit or the branch condition bit, and the positions those bits occupy in each page in the module address memory section 4 are arbitrary.

The conditions based on which the circuit control section 5 performs a jump are not limited to the above-described ones. For example, the conditions for executing a jump should not necessarily depend on the values of the signals Cond(0) to Cond(4), and the number of bits of the signal Cond need not be 5 bits. The condition may relate to another arbitrary information that can be acquired by the circuit control section 5.

The signal Cond may represent the value of a signal which is acquired as a consequence of performing a predetermined process, such as logical operations, on the value of a signal generated at a single node of the logic circuit section 1, or the values of signals generated at plural nodes at one timing or plural timings. In this case, the logic circuit section 1 should include a logic circuit which performs the logical operations.

The circuit control section 5 may make an absolute jump as well as the above-described kind of jump (i.e., a relative jump). In this case, the branch control bit to be stored in the module address memory section 4 has only to represent three kinds of instructions, such as a relative jump, an absolute jump and no jump executed. When the branch control bit indicates an absolute jump, the circuit control section 5 interprets that the page address to jump is stored in the page including the branch control bit instead of the offset value (i.e., the page address to jump should be stored in that page in place of the offset value).

The programmable logic circuit control apparatus according to the embodiment of the invention, which has been discussed so far, is not limited to an exclusive system, but can be achieved by using an ordinary computer system. For example, the programmable logic circuit control apparatus executes the above-described processes can be achieved by installing programs for executing the operations of the internal data memory 2, the module memory section 3, the module address memory section 4 and the circuit control section 5 into, for example, a computer connected to the logic circuit section 1 from a medium (CD-ROM, MO or the like) where the programs are stored.

Alternatively, such a program may be uploaded to, for example, a bulletin board system (BBS) of a communication circuit, and may be distributed through the communication circuit. A carrier wave may be modulated with a signal representing the program, the acquired modulated waveform may be transmitted, and the apparatus which has received the modulated waveform may demodulate the modulated waveform to restore the program. Further, the processes discussed above may be executed by activating the program and running the program under the control of the OS in the same manner as another application program is run.

When the OS takes a part in performing a part of the processes, or the OS constitutes a part of one constitutional element of the invention, a program excluding that part may be stored in a recording medium. In this case, a program for executing the individual functions or steps that a computer executes should be stored in that recording medium.

Various embodiments and changes may be made thereunto without departing from the broad spirit and scope of the invention. The above-described embodiment is intended to illustrate the present invention, not to limit the scope of the present invention. The scope of the present invention is shown by the attached claims rather than the embodiment. Various modifications made within the meaning of an equivalent of the claims of the invention and within the claims are to be regarded to be in the scope of the present invention.

This application is based on Japanese Patent Application No. 2004-42701 filed on Feb. 19, 2004 and including specification, claims, drawings and summary. The disclosure of the above Japanese Patent Application is incorporated herein by reference in its entirety.

1. A programmable logic circuit control system for controlling a logical structure of a programmable logic circuit, comprising:
a controller (5) which controls said logical structure of said programmable logic circuit (1) by supplying a control signal to said programmable logic circuit;
a module memory (3) which stores a plurality of modules each comprised of data defining said logical structure of said programmable logic circuit;
a module designation memory (4) which has a plurality of ordered memory areas and stores data designating an address of a module in at least one of said memory areas;
a node value memory (2) which receives a signal generated at a predetermined node of said programmable logic circuit to be controlled and stores a value represented by said signal,
wherein said node value memory (2) has a plurality of memory areas to which read addresses different from one another and write addresses different from one another are respectively allocated, and has a write function of writing a value represented by said signal generated at said predetermined node of said programmable logic circuit in that memory area to which a write address indicated by a write address signal supplied is allocated, a read function of supplying said programmable logic circuit to be controlled with a signal representing a value stored in that memory area to which a read address indicated by a read address signal supplied is allocated,
a read address and a write address associated with a module are further stored in that memory area in said module designation memory (4) where data designating an address of that module is stored, and
said controller (5) has a function of acquiring data stored in a memory area in said module designation memory (4), a function of acquiring a module indicated by an address included in said data acquired from said module designation memory (4), generating a control signal for causing said programmable logic circuit (1) to take a logical structure indicated by said module, and supplying said control signal to said programmable logic circuit (1), thereby changing said logical structure of said programmable logic circuit (1), and a function of supplying a read address and a write address included in said data acquired from said module designation memory (4) to said node value memory.

2. The programmable logic circuit control system according to claim 1, wherein said controller (5) is formed by changing a part of said logical structure of said programmable logic circuit (1).

3. The programmable logic circuit control system according to claim 1, wherein said node value memory (2) is formed by changing a part of said logical structure of said programmable logic circuit.

4. The programmable logic circuit control system according to claim 1, wherein said node value memory (2) is constructed in such a way as to be able to independently perform said write function and said read function, and
said controller (5) has a structure capable of performing a function of supplying a write address to said node value memory and a function of supplying a read address to said node value memory (2) in parallel.

5. The programmable logic circuit control system according to claim 1, wherein said module designation memory (4) stores an address of a module or data designating another memory area in each memory area, and
said controller (5) discriminates whether data acquired from a memory position in said module designation memory (4) designates an address of a module or data designating another memory area,
acquires said module indicated by said address from said module memory (3) when discriminating that said data designates said address of said module, and generates a control signal for causing said programmable logic circuit (1) to be controlled to take a logical structure indicated by said module, and supplies said control signal to said programmable logic circuit, thereby changing said logical structure of said programmable logic circuit, and
acquires data stored at another memory position from said module designation memory (4) when discriminating that said data acquired from said module designation memory designates said another memory position.

6. The programmable logic circuit control system according to claim 5, wherein said data stored in said module designation memory (4) and designating said another memory area includes condition definition data designating a condition to go to a process of acquiring data stored in said another memory area,
when discriminating that said data designates said another memory area, said controller (5) discriminates whether said condition designated by said condition definition data included in said acquired data is fulfilled or not,
when discriminating that said condition is fulfilled, said controller (5) acquires data stored in said another memory area from said module designation memory (4), and
when discriminating that said condition is not fulfilled, said controller (5) aborts acquisition of data from said another memory area.

7. The programmable logic circuit control system according to claim 6, wherein said condition designated by said condition definition data included relates to a value represented by a signal generated at a predetermined node of said programmable logic circuit to be controlled,
when discriminating that said data acquired from said module designation memory (4) designating another memory position, said controller (5) acquires said signal from said node of said programmable logic circuit (1) to be controlled, and discriminates, based on said value represented by said acquired signal, whether said condition designated by said condition definition data included in said data acquired from said module designation memory (4) is fulfilled or not.

8. The programmable logic circuit control system according to claim 5, wherein said data stored at a memory position in said module designation memory (4) includes identification data for identifying which one of an address of a module and another memory position said data designates,
based on said identification data included in said data acquired from said module designation memory (4), said controller (5) discriminates whether said acquired data designates an address of a module or data designating another memory area.

9. A programmable logic circuit control apparatus having:
an acquiring section configured to acquire data stored at a memory position in a module designation memory, which has a plurality of ordered memory positions and stores data designating an address of a module at least one of said memory positions, from said module designation memory, wherein a read address and a write address allocated to a memory position in a node value memory are further stored at that memory position in said memory positions in said module designation memory where data designating said address of said module is stored,
said node value memory having a function of storing a value represented by a signal generated at a predetermined node of said programmable logic circuit to be controlled, at a memory position to which a write address locally supplied is allocated, and a function of supplying a signal representing a value stored at a memory position to which a read address locally supplied is allocated, to said programmable logic circuit to be controlled;
said programmable logic circuit control apparatus further comprising:
a write-address supply section configured to supply a write address included in said acquired data to said node value memory;
a change section configured to acquire a module indicated by an address included in said acquired data from a module memory, and to change a logical structure of said programmable logic circuit to be controlled in such a way as to cause said programmable logic circuit to take a logical structure indicated by said module; and
a read-address supply section configured to supply a read address included in said acquired data to said node value memory.

10. A programmable logic circuit control method which acquires a module comprised of data defining a logical structure of a programmable logic circuit to be controlled, and changes said logical structure of said programmable logic circuit to be controlled based on said acquired module, and comprises the steps of:
storing a plurality of modules each comprised of data defining said logical structure of said programmable logic circuit to be controlled;
acquiring data designating an address of a module and a signal generated at a predetermined node of said programmable logic circuit to be controlled, and stores a read address and a write address, allocated to that memory area in said node value memory which stores a value represented by said signal, at least one of a plurality of ordered memory positions for module use order designation;
acquiring data stored at said memory positions for module use order designation;
supplying a write address included in said acquired data to said node value memory;
acquiring a module indicated by an address included in said acquired data from said module memory, generating a control signal to cause said programmable logic circuit to be controlled to take a logical structure indicated by said module, and supplying said control signal to said programmable logic circuit to be controlled to change said logical structure of said programmable logic circuit to be controlled; and
supplying a read address included in said acquired data to said node value memory,
wherein said node value memory has a function of storing a value represented by a signal generated at a predetermined node of said programmable logic circuit to be controlled, at a memory position to which a write address locally supplied is allocated, and a function of supplying a signal representing a value stored at a memory position to which a read address locally supplied is allocated, to said programmable logic circuit to be controlled.

11. A programmable logic circuit control method which acquires a module comprised of data defining a logical structure of a programmable logic circuit to be controlled having a function of changing said logical structure according to a supplied control signal, from a module memory storing a plurality of modules, and generates a control signal for causing said programmable logic circuit to be controlled to take a logical structure indicated by said acquired module and supplies said control signal to said programmable logic circuit to be controlled, thereby changing said logical structure of said programmable logic circuit to be controlled, and comprises the steps of:
acquiring data stored at a memory position in a module designation memory, which has a plurality of ordered memory positions and stores data designating an address of a module at least one of said memory positions, from said module designation memory, wherein a read address and a write address allocated to a memory position in a node value memory are further stored at that memory position in said memory positions in said module designation memory where data designating said address of said module is stored, and said node value memory has a function of storing a value represented by a signal generated at a predetermined node of said programmable logic circuit to be controlled, at a memory position to which a write address locally supplied is allocated, and a function of supplying a signal representing a value stored at a memory position to which a read address locally supplied is allocated, to said programmable logic circuit to be controlled;
supplying a write address included in said acquired data to said node value memory;
acquiring a module indicated by an address included in said acquired data from a module memory, and changing a logical structure of said programmable logic circuit to be controlled in such a way as to cause said programmable logic circuit to take a logical structure indicated by said module; and
supplying a read address included in said acquired data to said node value memory.

12. A program for allowing a computer to function as:
a controller which supplies a control signal to a programmable logic circuit to be controlled having a function of changing a logical structure according to said supplied control signal, thereby changing said logical structure of said programmable logic circuit to be controlled;
a module memory which stores a plurality of modules each comprised of data defining said logical structure of said programmable logic circuit to be controlled;
a module designation memory which has a plurality of ordered memory positions and stores data designating an address of a module at least one of said memory positions; and
a node value memory which acquires a signal generated at a predetermined node of said programmable logic circuit to be controlled and stores a value represented by said signal,
wherein said node value memory has a plurality of memory positions to which read addresses and write addresses are allocated, and has a write function of storing a value represented by said signal generated at said predetermined node of said programmable logic circuit to be controlled at that memory position to which a write address locally supplied is allocated, a read function of supplying said programmable logic circuit to be controlled with a signal representing a value stored at that memory position to which a read address locally supplied is allocated,
a read address and a write address are further stored at that memory position in said module designation memory where data designating an address of that module is stored, and
said controller acquires data stored at a memory position in said module designation memory, supplies a write address included in said acquired data to said node value memory, acquires a module indicated by an address included in said data acquired from said module designation memory, generates a control signal for causing said programmable logic circuit to be controlled to take a logical structure indicated by said module, and supplies said control signal to said programmable logic circuit to be controlled, thereby changing said logical structure of said programmable logic circuit to be controlled, and supplies a read address included in said acquired data to node value memory.

13. A program for allowing a computer to function as a programmable logic circuit control apparatus which acquires a module comprised of data defining a logical structure of a programmable logic circuit to be controlled having a function of changing said logical structure according to a supplied control signal, from a module memory storing a plurality of modules, and generates a control signal for causing said programmable logic circuit to be controlled to take a logical structure indicated by said acquired module and supplies said control signal to said programmable logic circuit to be controlled, thereby changing said logical structure of said programmable logic circuit to be controlled,
said programmable logic circuit control apparatus comprising:
a section that acquires data stored at a memory position in a module designation memory, which has a plurality of ordered memory positions and stores data designating an address of a module at least one of said memory positions, from said module designation memory, wherein a read address and a write address allocated to a memory position in a node value memory are further stored at that memory position in said memory positions in said module designation memory where data designating said address of said module is stored,
said node value memory which has a function of storing a value represented by a signal generated at a predetermined node of said programmable logic circuit to be controlled, at a memory position to which a write address locally supplied is allocated, and a function of supplying a signal representing a value stored at a memory position to which a read address locally supplied is allocated, to said programmable logic circuit to be controlled;
a section which supplies a write address included in said acquired data to said node value memory;
a section which acquires a module indicated by an address included in said acquired data from a module memory, and changes a logical structure of said programmable logic circuit to be controlled in such a way as to cause said programmable logic circuit to take a logical structure indicated by said module; and
a section which supplies a read address included in said acquired data to said node value memory.
